(19) United States
(12) Patent Application Publication
(10) Pub. No.: US 2022/0394881 A1
(43) Pub. Date: Dec. 8, 2022

(54) IN-VEHICLE ELECTRONIC CONTROL DEVICE

(71) Applicant: Hitachi Astemo, Ltd., Ibaraki (JP)

(72) Inventors: Yasuhiro TSUYUKI, Tokyo (JP); Yoshio KAWAI, Ibaraki (JP); Toshiaki ISHII, Tokyo (JP); Eiichi IDE, Tokyo (JP)

(73) Assignee: Hitachi Astemo, Ltd., Ibaraki (JP)

(21) Appl. No.: 17/776,857

(22) PCT Filed: Nov. 20, 2020
(86) PCT No.: PCT/JP2020/043334

§ 371 Date: May 13, 2022

(30) Foreign Application Priority Data
Dec. 5, 2019 (JP) 2019-220098

(51) Int. Cl. H05K 7/20; H05K 5/00

(52) U.S. Cl. CPC H05K 7/20463; H05K 7/20854; H05K 5/0056; H05K 5/03

(57) ABSTRACT

The present invention provides an in-vehicle electronic control device which further improves heat dissipation by forming a protrusion extending toward an electronic component on an inner surface of a cover portion formed of a highly thermally conductive resin in consideration of orientation of a filling material contained in the highly thermally conductive resin. An in-vehicle electronic control device of the present invention includes: a circuit board on which an electronic component is mounted; a base portion in which the circuit board is installed; and a cover portion with which the circuit board is covered together with the base portion, which is formed of a resin containing a filling material, and which has a protrusion protruding toward the electronic component, in which the protrusion is formed of a resin containing a filling material and a width of the protrusion is smaller than a width of the electronic component.

### TECHNICAL FIELD

The present invention relates to an in-vehicle electronic control device.

### BACKGROUND ART

With increase in functionality of in-vehicle electronic control devices, amounts of heat generated due to electronic components installed in the in-vehicle electronic control device are increasing. In-vehicle electronic control devices use heat dissipation structures in which heat dissipation blocks and heat dissipation members installed in housings or the like are thermally connected and dissipate heat.

On the other hand, although in-vehicle electronic control devices have used metal materials for housings in the related art, in recent years, highly thermally conductive resins have been used for the housings and weight reduction has been promoted.

However, since the thermal conductivity of the housings decreases in the in-vehicle electronic control devices in which highly thermally conductive resins are used for the housings, in the heat dissipation structure in which the heat dissipation blocks and the heat dissipation member installed in the housings or the like are thermally connected and dissipate heat, the ability to dissipate heat decreases and the temperature of electronic components increases.

As background art of this technical field described above, there is JP 2011-192937 A (PTL 1).

PTL. 1 describes an electronic control device for an automobile which includes a circuit board on which a heat generating element is mounted and a housing which accommodates the circuit board therein and has a main body and a lid. In the electronic control device for an automobile, a protrusion extending toward the heat generating element is formed on an inner surface of the lid of the housing which houses the circuit board therein to be close to the heat generating element mounted on the circuit board, heat generated in the heat generating element is transmitted to the lid through the protrusion, and the heat is released from an outer surface of the lid to the atmosphere (refer to Abstract).

### CITATION LIST

### Patent Literature

PTL 1: JP 2011-192937 A

### SUMMARY OF INVENTION

### Technical Problem

PTL 1 discloses an electronic control device for a vehicle (in-vehicle electronic control device) in which a protrusion extending toward an electronic component is formed on an inner surface of a lid (cover portion) of a housing that accommodates a circuit board on which a heat generating element (electronic component) is mounted therein.

However, PTL 1 does not describe that a highly thermally conductive resin obtained by mixing a resin and a filling material is used for a cover portion and a protrusion extending toward an electronic component is formed on an inner surface of the cover portion in consideration of an orientation of the filling contained in the highly thermally conductive resin.

Therefore, the present invention provides an in-vehicle electronic control device which further improves heat dissipation by forming a protrusion extending toward an electronic component on an inner surface of a cover portion formed of a highly thermally conductive resin in consideration of an orientation of a filling material contained in the highly thermally conductive resin.

### Solution to Problem

In order to solve the above problems, an in-vehicle electronic control device according to the present invention includes: a circuit board on which an electronic component is mounted; a base portion in which the circuit board is installed; and a cover portion with which the circuit board is covered together with the base portion, which is formed of a resin containing a filling material, and which has a protrusion protruding toward the electronic component, in which the protrusion is formed of a resin containing a filling material and a width of the protrusion is smaller than a width of the electronic component.

### Advantageous Effects of Invention

According to the present invention, the protrusion extending toward the electronic component is formed on the inner surface of the cover portion formed of the highly thermally conductive resin in consideration of the orientation of the filling material contained in the highly thermally conductive resin. Thus, it is possible to provide the in-vehicle electronic control device which further improves the heat dissipation.

Note that, problems, configurations, and effects other than those described above will be clearly provided by the following description of embodiments.

### BRIEF DESCRIPTION OF DRAWINGS

FIG. 1 is an exploded perspective view for explaining a basic configuration of an in-vehicle control device 1 described in a first embodiment.

FIG. 2 is a cross-sectional view for explaining an in-vehicle control device 1 in the vicinity of an electronic component 11 described in the first embodiment.

FIG. 3 is a cross-sectional view for explaining a filling material oriented in a protrusion 140 in the in-vehicle control device 1 in the vicinity of the electronic component 11 described in the first embodiment.

FIG. 4 is a cross-sectional view for explaining a filling material oriented in a protrusion 140 in an in-vehicle control device 1 in the vicinity of an electronic component 11 described in a second embodiment.

FIG. 5 is a cross-sectional view for explaining an in-vehicle control device 1 in the vicinity of an electronic component 11 described in a third embodiment.

FIG. 6 is a cross-sectional view for explaining an in-vehicle control device 1 in the vicinity of an electronic component 11 described in a comparative example.

FIG. 7 is a cross-sectional view for explaining an in-vehicle control device 1 in the vicinity of an electronic component 11 described in a fourth embodiment.

FIG. 8 is a cross-sectional view for explaining an in-vehicle control device 1 in the vicinity of an electronic component 11 described in a fifth embodiment.

FIG. 9 is a cross-sectional view for explaining an in-vehicle control device 1 in the vicinity of an electronic component 11 described in a sixth embodiment.

FIG. 10 is a cross-sectional view for explaining an in-vehicle control device 1 in the vicinity of an electronic component 11 described in a seventh embodiment.

FIG. 11A is a top view for explaining a relationship A between a width of a protrusion 140 and a width of an electronic component 11.

FIG. 11B is a top view for explaining a relationship B between the width of the protrusion 140 and the width of the electronic component 11.

FIG. 11C is a top view for explaining a relationship C between the width of the protrusion 140 and the width of the electronic component 11.

FIG. 11D is a top view for explaining a relationship D between the width of the protrusion 140 and the width of the electronic component 11.

FIG. 11E is a top view for explaining a relationship E between the width of the protrusion 140 and the width of the electronic component 11.

FIG. 11F is a top view for explaining a relationship F between the width of the protrusion 140 and the width of the electronic component 11.

FIG. 11G is a top view for explaining a relationship G between the width of the protrusion 140 and the width of the electronic component 11.

### DESCRIPTION OF EMBODIMENTS

Embodiments of the present invention will be described below with reference to the drawings. Note that substantially the same or similar configurations are denoted by the same reference numerals, and in the case in which descriptions thereof overlap, the description thereof may be omitted in some cases.

### First Embodiment

First, a basic configuration of an in-vehicle control device 1 described in a first embodiment will be described.

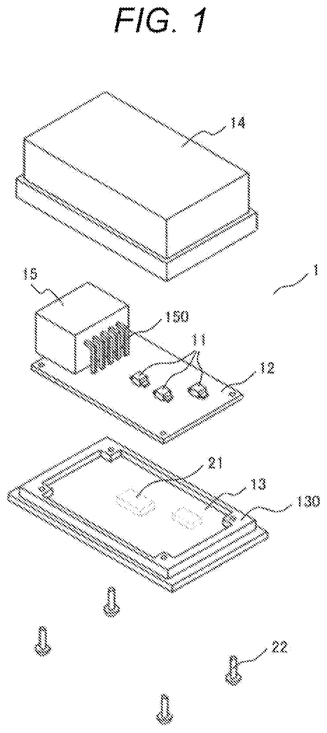

FIG. 1 is an exploded perspective view for describing the basic configuration of the in-vehicle control device 1 described in the first embodiment.

The in-vehicle control device 1 described in the first embodiment is a box-type in-vehicle control device and includes a circuit board 12 and a housing which accommodates the circuit board 12 therein and includes a base portion 13 and a cover portion 14.

On one surface and/or both surfaces of the circuit board 12, an electronic component 11 which generates heat such as a semiconductor element and a passive component (not illustrated) such as a resistor and a capacitor constituting an electronic circuit are electrically connected (mounted) using a conductive connection material such as solder. Note that, In the first embodiment, the electronic component 11 is installed (mounted) in (on) an upper surface of the circuit board 12. Note that screw holes are formed at four corners of the circuit board 12.

A connector 15 which electrically connects the circuit board 12 and the outside is installed on the circuit board 12. A required number of pin terminals 150 are connected to the connector 15 by press-fitting, soldering, or the like. The pin terminals 150 are also connected to the circuit board 12 by press-fitting, soldering, or the like. That is to say, the connector 15 and the circuit board 12 are electrically connected via the pin terminals 150.

As the circuit board 12, a general laminated wiring board including a thermosetting resin, a glass cloth, and a metal wiring on which a circuit pattern is formed, a wiring board including ceramics and a metal wiring, a wiring board including a flexible substrate formed of polyimide or the like and a metal wiring, or the like is used.

The circuit board 12 is installed in the base portion 13. A rectangular protrusion 21 is installed in the base portion 13. The rectangular protrusion 21 is formed to face the electronic component 11 via the circuit board 12. Note that it is preferable that the rectangular protrusion 21 be formed integrally with the base portion 13. Stand portions 130 are installed at four corners of the base portion 13. A screw hole is formed in each of the stand portions 130. It is preferable that the stand portion 130 be formed integrally with the base portion 13.

The base portion 13 is formed by casting, pressing, cutting, injection molding, or the like.

The base portion 13 is formed of a highly thermally conductive resin in which a resin and a filling material (filler) are mixed. The thermal conductivity of the highly thermally conductive resin is preferably 2 to 30 W/(m·K). However, the base portion 13 is not limited to a highly thermally conductive resin and may be any resin or a metal material.

Note that it is preferable that the resin be a polybutylene terephthalate resin (PBT), a polyphenylene sulfide resin (PPS), a polyamide resin (PA6), or the like. It is preferable that the filling material be glass fibers, carbon fibers, alumina (Al₂O₃), or the like. Also, it is preferable that the metal material be aluminum (Al).

The cover portion 14 has a box type shape in which a lower surface of the cover portion is open. Note that screw holes are formed at four corners of the cover portion 14.

The cover portion 14 is formed by casting, pressing, cutting, injection molding, or the like.

The cover portion 14 is formed of a resin containing a filling material. Also, it is preferable that the cover portion 14 be formed of a highly thermally conductive resin obtained by mixing a resin and a filling material. The thermal conductivity of the highly thermally conductive resin is preferably 2 to 30 W/(m·K).

Note that it is preferable that the resin be any one of a polybutylene terephthalate resin (PBT), a polyphenylene sulfide resin (PPS), a polyamide resin (PA6), and the like. Also, it is preferable that the filling material be any one of glass fiber, carbon fiber, alumina (Al2O3), and the like.

Furthermore, the base portion 13 and the cover portion 14 are assembled by causing the circuit board 12 having the connector 15 installed therein to be disposed therebetween. That is to say, the circuit board 12 is installed in the base portion 13 and the cover portion 14 is installed so that the circuit board 12 is covered with the cover portion 14.

The circuit board 12 is disposed between the stand portions 130 installed at the four corners of the base portion 13 and the cover portion 14 and is fixed to the base portion 13 and the cover portion 14 using fastening members (for example, set screws 22).

Note that a method of fixing the cover portion 14 and the base portion 13 is not limited to the method of screwing and fixing using the set screw 22. For example, a method of fitting and fixing the base portion 13 and the cover portion 14 using an assembly hole provided in an upright portion rising from the base portion 13 and protrusions to be installed on the cover portion 14, a method of bonding and fixing the base portion 13 and the cover portion 14, and the like may be used.

The in-vehicle control device 1 in the vicinity of the electronic component 11 described in the first embodiment will be described below.

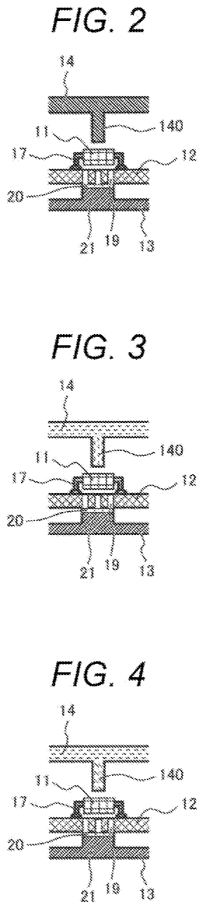

FIG. 2 is a cross-sectional view for explaining the in-vehicle control device 1 in the vicinity of the electronic component 11 described in the first embodiment.

Thermal vias 19 are provided in the circuit board 12 and are formed immediately below the electronic components 11. That is to say, in the circuit board 12 immediately below the electronic component 11, the thermal vias 19 which pass through an upper surface of the circuit board 12 and a lower surface of the circuit board 12 and release the heat generated in the electronic component 11 through the circuit board 12 are formed.

Note that the electronic component 11 is electrically connected to the circuit board 12 via a wire bonding terminal 17.

A rectangular protrusion 21 is provided in a portion located immediately below the thermal vias 19. That is to say, the rectangular protrusion 21 protruding and installed on the base portion 13 is formed to face the electronic component 11 via the circuit board 12.

A heat dissipation member 20 to be thermally connected is installed between a lower surface of the circuit board 12 and an upper surface of the rectangular protrusion 21. The heat dissipation member 20 has a function as an adhesive or grease (lubricant) and is preferably a material obtained by incorporating a filling material having high thermal conductivity into a sheet-like thermoplastic or thermosetting silicone or epoxy resin.

Also, a protrusion (hanging portion) 140 which efficiently releases heat generated due to the electronic component 11 is formed on the cover portion 14. Note that the protrusion 140 is formed integrally with the cover portion 14.

That is to say, the protrusion 140 is also formed by casting, pressing, cutting, injection molding, or the like together with the cover portion 14.

Similarly to the cover portion 14, the protrusion 140 is also formed of a resin containing a filling material. It is preferable that the protrusion 140 be made of a highly thermally conductive resin obtained by mixing a resin and a filling material. The thermal conductivity of the highly thermally conductive resin is preferably 2 to 30 W/(m·K).

As described above, the circuit board 12 is covered with the cover portion 14 together with the base portion 13 and the cover portion 14 is formed of a resin containing a filling material and has the protrusion 140 protruding toward the electronic component 11. As a result, heat generated in the electronic component 11 is not retained between the lower surface of the protrusion 140 and the upper surface of the electronic component 11, but is absorbed from the lowermost portion of the protrusion 140 and dissipated from the cover portion 14 to the atmosphere.

Note that, in order to efficiently release the heat generated due to the electronic component 11, it is preferable that the lower surface of the protrusion 140 be formed up to immediately before the upper surface of the electronic component 11. Note that the expression “up to just before” means that the lower surface of the protrusion 140 is close to the extent that the lower surface is not in contact with the upper surface of the electronic component 11. For example, a distance between the lower surface of the protrusion 140 and the upper surface of the electronic component 11 is 0.5 to 1.5 mm.

As described above, a heat dissipation structure for heat generated in the electronic component 11 in the case in which a highly thermally conductive resin is used for the housing is more important than that in the case in which a metal material is used for the housing.

In addition, a strength of the housing in the case in which a highly thermally conductive resin is used for the housing is lower than that in the case in which a metal material is used for the housing. In the case in which a highly thermally conductive resin is used for the housing, it is also important to maintain the strength of the housing, particularly, to prevent warpage of the cover portion 14.

In addition, it is preferable that a width of the protrusion 140 (a length of the protrusion 140 in a direction of the surface in which the lower surface of the protrusion 140 and the upper surface of the electronic component 11 face each other) be smaller than a width of the electronic component 11 (a length of the electronic component 11 in a direction of the surface in which the lower surface of the protrusion 140 and the upper surface of the electronic component 11 face each other) (thin protrusion 140). For example, in the case in which the width of the electronic component 11 is 1.00, the width of the protrusion 140 is preferably 0.40 to 0.95.

Furthermore, the width of the protrusion 140 is preferably 10 to 20 mm.

In addition, a ratio (aspect ratio (X/Y)) of a width (X) of the protrusion 140 to a length (Y) from an end portion on the electronic component 11 side to an end portion on the cover portion 14 side is preferably 3/10 or less and a maximum value of the width of the protrusion 140 is preferably 20 mm. Note that the end portion on the cover portion 14 side is a side in contact with the cover portion 14 and the end portion on the electronic component 11 side is a side facing the electronic component 11.

According to the first embodiment, it is possible to achieve weight reduction of the cover portion 14, improve heat dissipation of the protrusion 140, and prevent warpage of the cover portion 14.

Here, relationships (A, B, C, D, E, F, and G) between the width of the protrusion 140 and the width of the electronic component 11 will be described.

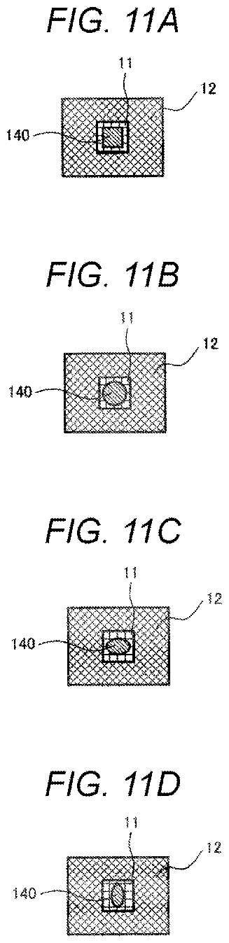

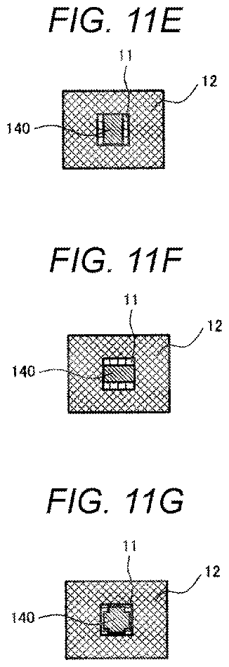

FIGS. 11A, 11B, 11C, 11D, 11E, 11F, and 11G are top views for explaining the relationships (A, B, C, D, E, F, and G) between the width of the protrusion 140 and the width of the electronic component 11.

FIG. 11A illustrates the relationship A, FIG. 11B illustrates the relationship B, FIG. 11C illustrates the relationship C, FIG. 11D illustrates the relationship D, FIG. 11E illustrates the relationship E, FIG. 11F illustrates the relationship F, and FIG. 11G illustrates the relationship G.

Although the electronic component 11 has a square cross-sectional shape in the first embodiment, the cross-sectional shape is not limited to a square shape and may be a rectangle.

For the electronic component 11 having a square cross-sectional shape, the cross-sectional shape of the protrusion 140 is a square in the relationship A, a circle in the relationship B, an ellipse long in a leftward/rightward direction in the drawing in the relationship C, an ellipse long in an upward/downward direction in the drawing in the relationship D, a rectangle long in the upward/downward direction in the drawing in the relationship E, a rectangle long in the leftward/rightward direction in the drawing in the relationship F, and a cross in the relationship G. Note that, here, although a square, a circle, an ellipse, a rectangle, and a cross are shown, the shapes are not limited thereto.

As described above, the width of the protrusion 140 being smaller than the width of the electronic component 11 means that the width of the protrusion 140 in a vertical direction in the drawing and/or a horizontal direction in the drawing is smaller than the width of the electronic component 11 having a square cross-sectional shape in the vertical direction in the drawing and the horizontal direction in the drawing.

However, it is not necessary that the width of the protrusion 140 be small with the width of the electronic component 11 having a square cross-sectional shape in the vertical direction in the drawing and the horizontal direction in the drawing, and it is sufficient that the width of the protrusion 140 be small with the width of the electronic component 11 having a square cross-sectional shape in the vertical direction in the drawing or the horizontal direction in the drawing (including a case in which the width is partially small like a cross).

The width of the protrusion 140 in the vertical direction in the drawing and the horizontal direction in the drawing is equal to or less than the width of the electronic component 11 in the vertical direction in the drawing and the horizontal direction in the drawing. That is to say, the entire lower surface of the protrusion 140 faces the upper surface of the electronic component 11.

That is to say, the protrusion 140 is formed at a position in which the protrusion 140 and the electronic component 11 overlap in a thickness direction of the circuit board 12. In addition, in the thickness direction of the circuit board 12, it is preferable that the lower surface of the protrusion 140 be formed at a position in which the lower surface of the protrusion 140 and a center of the upper surface of the electronic component 11 overlap. Furthermore, it is preferable that the protrusion 140 be formed such that the center of the lower surface of the protrusion 140 and the center of the upper surface of the electronic component 11 coincide with each other in the thickness direction of the circuit board 12. As a result, heat dissipation from the electronic component 11 to the cover portion 14 is improved.

As described above, in the first embodiment, the thin protrusion 140 is formed on the cover portion 14. As a result, when the protrusion 140 is formed, the filling material contained in the highly thermally conductive resin is oriented at the protrusion 140. Due to the filling material oriented at the protrusion 140, heat is easily transferred from the protrusion 140 to the cover portion 14 and heat dissipation is improved.

The protrusion 140 is formed on the inner surface of the cover portion 14 to extend (protrude) toward the electronic component 11 in consideration of the orientation of the filling material contained in the highly thermally conductive resin (a direction in which particles of the filling material are arranged). Also, the heat generated due to the electronic component 11 is absorbed from the lowermost portion of the protrusion 140 and dissipated from the cover portion 14 to the atmosphere.

As described above, in the in-vehicle control device 1 described in the first embodiment, the heat generated in the electronic component 11 is transmitted to the base portion 13, the protrusion 140, and the cover portion 14, and is dissipated to the atmosphere.

That is to say, in the first embodiment, in consideration of the orientation of the filling material contained in the highly thermally conductive resin, the protrusion 140 extending toward the electronic component 11 is formed on the inner surface of the cover portion 14 so that the heat dissipation can be further improved.

For example, although the heat dissipation temperature of the electronic component 11 (3.5 W) in the case in which a metal material (used for aluminum, thermal conductivity is 90 W/(m·K)) is used for the housing is 137.0° C., the heat dissipation temperature of the electronic component 11 (3.5 W) in the case in which a highly thermally conductive resin (polybutylene terephthalate resin is used for the resin and alumina is used for the filling material, and the thermal conductivity was 30 to 10 W/(m·K) in accordance with the content of the filling material) is used for the housing is 146.5 to 147.0° C.

The in-vehicle electronic control device described in the first embodiment includes: a circuit board 12 on which an electronic component 11 is mounted; a base portion 13 in which the circuit board 12 is installed; and a cover portion 14 with which the circuit board 12 is covered together with the base portion 13, which is formed of a resin containing a filling material, and which has a protrusion 140 protruding toward the electronic component 11. In addition, the protrusion 140 is formed of a resin containing a filling material, and in consideration of heat dissipation of the cover portion 14 and warpage of the cover portion 14, a width of the protrusion 140 is made smaller than a width of the electronic component 11.

According to the first embodiment, it is possible to provide an in-vehicle electronic control device which achieves weight reduction of the cover portion 14, improves heat dissipation of the protrusion 140, and prevents warpage of the cover portion 14.

In the in-vehicle control device 1 in the vicinity of the electronic component 11 described in the first embodiment, the filling material oriented in the protrusion 140 will be described below.

FIG. 3 is a cross-sectional view for explaining the filling material oriented in the protrusion 140 in the in-vehicle control device 1 in the vicinity of the electronic component 21 described in the first embodiment.

At the protrusion 140, the filling material is oriented in the vertical direction (from the electronic component 11 toward the cover portion 14 or from the cover portion 14 toward the electronic component 11). That is to say, in the protrusion 140, the filling material is oriented in a direction perpendicular to a surface in which the lower surface of the protrusion 140 and the upper surface of the electronic component 11 face each other. This improves heat dissipation of the protrusion 140.

Note that, in FIG. 3, dotted lines indicated in the cover portion 14 (lateral direction) and the protrusion 140 (longitudinal direction) schematically indicate an orientation model of the filling material (arrangement direction of particles of the filling material).

Here, being oriented in the vertical direction or being oriented in the vertical direction means that, in the protrusion 140, the filling material is oriented in a range from the vertical direction (0 degrees) to 45 degrees with respect to the surface in which the lower surface of the protrusion 140 and the upper surface of the electronic component 11 face each other.

In the case in which the cover portion 14 is formed by, for example, injection molding, the cover portion 14 is formed by utilizing a mold having a portion in which the protrusion 140 is formed as a gate inlet or a gate outlet and flowing in a resin containing a filling material from the gate inlet or flowing out the resin from the gate outlet. As a result, the filling material is oriented in the vertical direction at the thin protrusion 140.

Furthermore, since the filling material is oriented in the vertical direction in the protrusion 140, a thermal resistance value per unit area in the vertical direction with respect to the surface in which the lower surface of the protrusion 140 and the upper surface of the electronic component 11 face each other is smaller than a thermal resistance value per unit area in the horizontal direction with respect to the surface in which the lower surface of the protrusion 140 and the upper surface of the electronic component 11 face each other.

Here, the horizontal direction is a range from the vertical direction (0 degrees) to more than 45 degrees and up to 90 degrees with respect to the surface in which the lower surface of the protrusion 140 and the upper surface of the electronic component 11 face each other.

As described above, by using the resin containing the filling material and forming the thin protrusion 140, the filling material is oriented in the vertical direction at the thin protrusion 140 and the heat dissipation from the electronic component 11 to the cover portion 14 is improved.

### Second Embodiment

In an in-vehicle control device 1 in the vicinity of an electronic component 11 described in a second embodiment, a filling material oriented in a protrusion 140 will be described below.

FIG. 4 is a cross-sectional view for explaining the filling material oriented in the protrusion 140 in the in-vehicle control device 1 in the vicinity of the electronic component 11 described in the second embodiment.

In the second embodiment, an orientation ratio of the filling material in the protrusion 140 is different from that in the first embodiment.

That is to say, in the first embodiment, the filling material is oriented in the vertical direction at the protrusion 140. At the protrusion 140, the filling material is oriented in a direction perpendicular to the surface in which a lower surface of the protrusion 140 and an upper surface of the electronic component 11 face each other.

On the other hand, in the second embodiment, the filling material is oriented slightly inclined from the vertical direction at the protrusion 140. At the protrusion 140, the filling material is oriented slightly inclined from the vertical direction with respect to the surface in which the lower surface of the protrusion 140 and the upper surface of the electronic component 11 face each other.

In the first embodiment, a proportion A1 of the filling material oriented in the vertical direction in the protrusion 140 is larger than a proportion B1 of the filling material oriented in the horizontal direction. That is to say, A1>B1 and A1−B1>0 are satisfied.

Also in the second embodiment, a proportion A2 of the filling material oriented in the vertical direction in the protrusion 140 is larger than a proportion B2 of the filling material oriented in the horizontal direction. That is to say, A2>B2 and A2−B2>0 are satisfied. However, in the second embodiment, the proportion B2 of the filling material oriented in the horizontal direction is larger than the proportion B1 of the filling material oriented in the horizontal direction. That is to say, B2>B1 is satisfied. Note that A1>A2 is satisfied. That is to say, in the second embodiment, the filling material is oriented slightly inclined from the vertical direction at the protrusion 140.

This makes it easy to control the orientation of the protrusion 140. The heat dissipation from the electronic component 11 to the cover portion 14 is also improved.

Note that, also in the second embodiment, the orientation of the filling material in the protrusion 140 is 45 degrees or less from the direction (0 degrees) perpendicular to the surface in which the lower surface of the protrusion 140 and the upper surface of the electronic component 11 face each other.

### Third Embodiment

An in-vehicle control device 1 in the vicinity of an electronic component 11 described in a third embodiment will be described below.

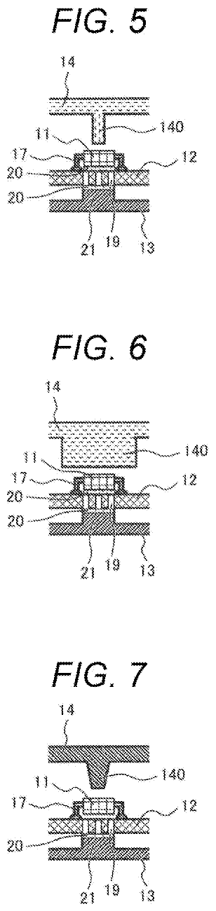

FIG. 5 is a cross-sectional view for explaining the in-vehicle control device 1 in the vicinity of the electronic component 11 described in the third embodiment.

The in-vehicle control device 1 described in the third embodiment is different from the in-vehicle control device 1 described in the first embodiment in terms of a position in which a heat dissipation member 20 is installed.

That is to say, in the first embodiment, the heat dissipation member 20 is installed between the lower surface of the circuit board 12 and the upper surface of the rectangular protrusion 21.

On the other hand, in the third embodiment, the heat dissipation member 20 is installed between the lower surface of the circuit board 12 and the upper surface of the rectangular protrusion 21 and between the upper surface of the circuit board 12 and the lower surface of the electronic component 11. As a result, heat dissipation from the electronic component 11 to the base portion 13 is improved.

The in-vehicle control device 1 described in the third embodiment includes a circuit board 12 on which an electronic component 11 is mounted, a base portion 13 in which the circuit board 12 is installed, and a cover portion 14 with which the circuit board 12 is covered together with the base portion 13, which is formed of a resin containing a filling material, and which has a protrusion 140 protruding toward the electronic component 11 and a width of the protrusion 140 is made smaller than a width of the electronic component 11. Also, the filling material is oriented in the vertical direction (direction perpendicular to the surface in which the lower surface of the protrusion 140 and the upper surface of the electronic component 11 face each other) at the thin protrusion 140.

Here, the in-vehicle control device 1 in the vicinity of the electronic component 11 described in a comparative example will be described.

FIG. 6 is a cross-sectional view for explaining the in-vehicle control device 1 in the vicinity of the electronic component 11 described in the comparative example.

The in-vehicle control device 1 described in the comparative example includes: a circuit board 12 on which an electronic component 11 is mounted; a base portion 13 in which the circuit board 12 is installed; and a cover portion 14 with which the circuit board 12 is covered together with the base portion 13, which is formed of a resin containing a filler, and which has a protrusion 140 protruding toward the electronic component 11 and a width of the protrusion 140 is larger than a width of the electronic component 11 (thick protrusion 140). The filling material is oriented in the leftward/rightward direction (the direction horizontal to the surface in which the lower surface of the protrusion 140 and the upper surface of the electronic component 11 face each other) at the thick protrusion 140.

That is to say, the in-vehicle control device 1 described in the comparative example is different from the in-vehicle control device 1 described in the third embodiment in terms of the width of the protrusion 140 and the orientation direction of the filling material at the protrusion 140.

Here, Table 1 shows the comparison between the third embodiment with the comparative example.

TABLE 1

| | Direction in which | Temperature of |
|---|---|---|
| | filling material | 3.5 W electronic |
| | is oriented | component (° C.) |
| Embodiment | Vertical | 145.9 |
| Comparative | Horizontal | 147.5 |
| example | | |

As shown in Table 1, in the third embodiment, the heat dissipation temperature of the electronic component 11 (3.5 W) is 145.9° C., and in the comparative example, the heat dissipation temperature of the electronic component 11 (3.5 W) is 147.5° C. That is to say, in the third embodiment, the heat dissipation temperature of the electronic component 11 (3.5 W) is lower by 1.6° C. than that in the comparative example.

In the comparative example, by using a resin containing a filling material and forming the thick protrusion 140, the filling material is oriented in the leftward/rightward direction at the thick protrusion 140 and the heat dissipation from the electronic component 11 to the cover portion 14 is small.

On the other hand, in the third embodiment, by using a resin containing a filling material and forming the thin protrusion 140, the filling material is oriented in the vertical direction at the thin protrusion 140 and the heat dissipation from the electronic component 11 to the cover portion 14 is large.

As described above, by forming the thin protrusion 140 extending toward the electronic component 11 in consideration of the orientation of the filling material contained in the resin, heat dissipation can be improved.

### Fourth Embodiment

An in-vehicle control device 1 in the vicinity of an electronic component 11 described in a fourth embodiment will be described below.

FIG. 7 is a cross-sectional view for explaining the in-vehicle control device 1 in the vicinity of the electronic component 11 described in the fourth embodiment.

The in-vehicle control device 1 described in the fourth embodiment is different from the in-vehicle control device 1 described in the first embodiment in terms of a shape of a protrusion 140.

That is to say, in the first embodiment, the width of the protrusion 140 on the side in contact with the cover portion 14 is the same as the width thereof on the side facing the electronic component 11.

On the other hand, in the fourth embodiment, the width of the protrusion 140 on the side facing the electronic component 11 is smaller than the width thereof on the side in contact with the cover portion 14. As a result, in the case in which the cover portion 14 is formed by, for example, injection molding, the fluidity of the resin containing the filling material is improved and the filling material can be easily oriented by the thin protrusion 140.

### Fifth Embodiment

An in-vehicle control device 1 in the vicinity of an electronic component 11 described in a fifth embodiment will be described below.

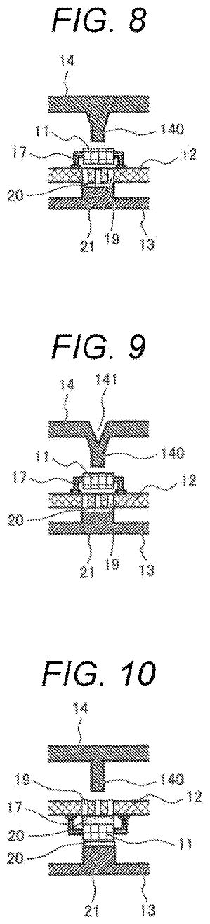

FIG. 8 is a cross-sectional view for explaining the in-vehicle control device 1 in the vicinity of the electronic component 11 described in the fifth embodiment.

The in-vehicle control device 1 described in the fifth embodiment is different from the in-vehicle control device 1 described in the first embodiment in terms of a shape of a protrusion 140.

That is to say, in the first embodiment, the width of the protrusion 140 on the side in contact with the cover portion 14 is the same as the width thereof on the side facing the electronic component 11.

On the other hand, in the fifth embodiment, the width of the protrusion 140 on the side facing the electronic component 11 is smaller than the width thereof on the side in contact with the cover portion 14. Furthermore, in the fifth embodiment, the protrusion 140 has the same width at the central portion in the vertical direction of the protrusion 140 and the same width on the side facing the electronic component 11. As a result, in the case in which the cover portion 14 is formed by, for example, injection molding, the fluidity of the resin containing the filling material is improved and the filling material can be easily oriented by the thin protrusion 140.

### Sixth Embodiment

An in-vehicle control device 1 in the vicinity of an electronic component 11 described in a sixth embodiment will be described below.

FIG. 9 is a cross-sectional view for explaining the in-vehicle control device 1 in the vicinity of the electronic component 11 described in the sixth embodiment.

The in-vehicle control device 1 described in the sixth embodiment is different from the in-vehicle control device 1 described in the first embodiment in terms of a shape of a protrusion 140.

That is to say, in the first embodiment, the width of the protrusion 140 on the side in contact with the cover portion 14 is the same as the width thereof on the side facing the electronic component 11.

On the other hand, in the sixth embodiment, the width of the protrusion 140 on the side facing the electronic component 11 is smaller than the width thereof on the side in contact with the cover portion 14. Furthermore, in the sixth embodiment, the protrusion 140 has the same width at the central portion in the vertical direction of the protrusion 140 and the same width on the side facing the electronic component 11. Furthermore, in the sixth embodiment, a recess 141 is formed in the cover portion 14. As a result, in the case in which the cover portion 14 is formed by, for example, injection molding, the fluidity of the resin containing the filling material is improved and the filling material can be easily oriented by the thin protrusion 140.

### Seventh Embodiment

An in-vehicle control device 1 in the vicinity of an electronic component 11 described in a seventh embodiment will be described.

FIG. 10 is a cross-sectional view for explaining the in-vehicle control device 1 in the vicinity of the electronic component 11 described in the seventh embodiment.

The in-vehicle control device 1 described in the seventh embodiment is different from the in-vehicle control device 1 described in the first embodiment in terms of a position in which an electronic component 11 is installed.

That is to say, in the first embodiment, the electronic component 11 is installed in the upper surface of the circuit board 12.

On the other hand, in the seventh embodiment, the electronic component 11 is installed in the lower surface of the circuit board 12.

Thermal vias 19 are provided in the circuit board 12 and are formed directly above the electronic components 11. That is to say, in the circuit board 12 immediately above the electronic component 11, the thermal vias 19 which pass through the upper surface of the circuit board 12 and the lower surface of the circuit board 12 and release the heat generated in the electronic component 11 through the circuit board 12 are formed.

Note that the electronic component 11 is electrically connected to the circuit board 12 via a wire bonding terminal 17.

A rectangular protrusion 21 is provided in a portion located immediately below the electronic component 11. That is to say, the rectangular protrusion 21 protruding from a base portion 13 is formed to face the electronic component 11.

A heat dissipation member 20 is installed between the lower surface of the circuit board 12 and the upper surface of the electronic component 11 and between the lower surface of the electronic component 11 and the upper surface of the rectangular protrusion 21.

Also, a protrusion 140 which efficiently releases heat generated by the electronic component 11 is formed on the cover portion 14. Note that the protrusion 140 is formed integrally with the cover portion 14.

In a tenth embodiment, the heat generated in the electronic component 11 is absorbed from the lowermost portion of the protrusion 140 via a heat dissipation member 20 and thermal vias 19 and is dissipated from the cover portion 14 to the atmosphere. As a result, heat dissipation from the electronic component 11 to the cover portion 14 is improved.

As described above, even in the case in which the thermal conductivity of the base portion 13 is low, the in-vehicle control device 1 of the present invention uses the heat dissipation from the cover portion 14 in addition to the heat dissipation from the base portion 13 and the heat generated in the electronic component 11 is dissipated from the housing to the atmosphere.

According to the present invention, in consideration of the orientation of the filling material contained in the highly thermally conductive resin, the protrusion 140 extending toward the electronic component 11 is formed on the inner surface of the cover portion 14 formed of the highly thermally conductive resin, and thus the heat dissipation can be further improved.

Note that the present invention is not limited to the above-described embodiments and includes various modifications. For example, the above-described embodiments have been specifically explained to describe the present invention in an easy-to-understand manner and are not necessarily limited to those having all the described configurations.

Furthermore, a part of the configuration of one embodiment can be replaced with a part of the configuration of another embodiment. In addition, the configuration of another embodiment can be added to the configuration of a certain embodiment. In addition, a part of the configuration of each embodiment can be deleted and a part of another configuration can be added and replaced with a part of another configuration.

### REFERENCE SIGNS LIST

1 in-vehicle control device
11 electronic component
12 circuit board
13 base portion
130 stand portion
14 cover portion
140 protrusion
141 recess
15 connector
150 pin terminal
17 wire bonding terminal
19 thermal via
20 heat dissipation member
21 rectangular protrusion
22 set screw

1. An in-vehicle electronic control device, comprising:
a circuit board on which an electronic component is mounted; a base portion in which the circuit board is installed; and
a cover portion with which the circuit board is covered together with the base portion, which is formed of a resin containing a filling material, and which has a protrusion protruding toward the electronic component,
wherein the protrusion is formed of a resin containing a filling material and a width of the protrusion is smaller than a width of the electronic component.

2. The in-vehicle electronic control device according to claim 1, wherein the protrusion has a thermal resistance value per unit area in a vertical direction smaller than a thermal resistance value per unit area in a horizontal direction.

3. The in-vehicle electronic control device according to claim 1, wherein a proportion of the filling material oriented in the vertical direction in the protrusion is larger than a proportion of the filling material oriented in the horizontal direction.

4. The in-vehicle electronic control device according to claim 1, wherein the orientation of the filling material in the protrusion is 45 degrees or less from the vertical direction.

5. The in-vehicle electronic control device according to claim 1, wherein the protrusion has a ratio of a width of the protrusion to a length from an end on an electronic component side to an end on a cover portion side of 3/10 or less and a maximum value of the width of the protrusion is 20 mm.

6. The in-vehicle electronic control device according to claim 1, wherein a lower surface of the protrusion faces an upper surface of the electronic component.

7. The in-vehicle electronic control device according to claim 6, wherein the protrusion is formed so that a center of a lower surface of the protrusion and a center of an upper surface of the electronic component coincide with each other in a thickness direction of the circuit board.

8. The in-vehicle electronic control device according to claim 1, wherein a width of an end portion of the protrusion on an electronic component side is smaller than a width of an end portion of the protrusion on a cover portion side.

9. The in-vehicle electronic control device according to claim 1, wherein the resin is any one of a polybutylene terephthalate resin, a polyphenylene sulfide resin, and a polyamide resin.

10. The in-vehicle electronic control device according to claim 1, wherein the filling material is any one of glass fiber, carbon fiber, and alumina.
